(19) United States
(12) Patent Application Publication
(10) Pub. No.: US 2002/0146865 A1
(43) Pub. Date: Oct. 10, 2002

(54) Method for selecting from standardized set of integrated circuit mask features

(76) Inventor: Jeffrey H. Hoel, Palo Alto, CA (US)

Correspondence Address: FISH & RICHARDSON P.C., 500 ARGUELLO STREET, SUITE 500, REDWOOD CITY, CA, 94063, US

(21) Appl. No.: 10/114,054

(22) Filed: Apr. 1, 2002

Related U.S. Application Data
(60) Provisional application No. 60/281,559, filed on Apr. 4, 2001.

(51) Int. Cl. H01L 21/82

(52) U.S. Cl. 438/130; 438/129; 438/128

(57) ABSTRACT

Methods and apparatus for manufacturing a semi-custom integrated circuit by using a standard mask and a custom mask to select from a standardized set of features in a way that obviates the need to create a customized mask containing only the selected features, and mask sets created using such methods and apparatus. For some integrated circuit fabrication processes, the second mask has an additional purpose, so it is not created only to perform this selection function. For some fabrication processes, the selection can be achieved without use of additional processing steps.

### BACKGROUND OF THE INVENTION

The present invention relates generally to the fabrication of semi-custom integrated circuits.

Generally, a process for fabricating integrated circuits builds integrated circuits on a wafer using a number of processing steps. Some of these steps are lithographic. In a lithographic step, a photoresist deposited on the wafer is exposed with a pattern, and then the photoresist is developed, so that it covers some portions of the wafer and not others. One or more subsequent processing steps then use the patterned photoresist to protect some portions of the wafer but not others from an operation such as etching or implantation of impurities.

Typically, a mask or reticle is used to provide the pattern with which photoresist is exposed during a lithographic step. In the description which follows, the term “mask” will be used generically to denote either a mask or a reticle. Typically, ultraviolet light is the illuminant, although X-rays or electrons can be used. It is also possible to expose photoresist with a direct-write electron beam exposure system, which uses a modulated electron beam and scanning technique, rather than a mask.

A semi-custom integrated circuit is an integrated circuit for which some of the lithographic steps are performed using standardized patterns, applicable to variety of purposes, and the remaining lithographic steps are performed using customized patterns, applicable only to a specific circuit of interest. When masks are used to provide these patterns, some of the masks are standardized and the rest are customized. Typically, most of the masks are standardized and only a few are customized. One advantage of semi-custom integrated circuits is that the cost of the standardized masks can be shared among a large number of designs. Another advantage is that wafers can be fabricated, using standardized masks, up to the point of the first customized lithographic step, and put into inventory, even before the customized masks for a specific design have been determined. When a specific design is completed, its customized masks are made, and partially fabricated wafers, taken from inventory, are further processed using the customized masks to create completed circuits. This procedure can significantly reduce the turnaround time for new designs.

Whether a mask for a semi-custom integrated circuit should be standardized or customized is sometimes not obvious. For example, consider a semi-custom design framework in which the top metal layer is customized and the penultimate metal layer is standardized. Should the via layer between these metal layers be standardized or customized? If it is customized, then each new design must pay for its own customized via mask. If it is standardized, then each design will fabricate far more vias than it actually uses, and the unused vias will add unwanted capacitance to penultimate metal interconnects and occupy space that could otherwise be more effectively used.

The dual damascene process has recently become popular for creating metal interconnects and vias. The process starts with a planarized wafer containing metal interconnects and intra-metal dielectric on its surface. Next, by some sequence of deposition, lithographic, and etching steps, one or more dielectric layers are deposited, and deep holes for vias and shallow trenches for interconnects are etched into the dielectric. Next, the via holes and trenches are filled with metal. Finally, excess metal is removed by chemical-mechanical polishing, leaving the wafer again planarized, with metal interconnects and intra-metal dielectric on its surface.

For some variants of the dual damascene process, mask patterns from both the metal mask and the via mask are present on the wafer simultaneously. The apparent purpose is to make the vias self-aligned to the metal interconnects. One such variant is described by B. El-Kareh in Fundamentals of Semiconductor Processing Technologies, Kluwer Academic Publishers, 1995, p. 564. Another is described by S. Wolf and R. N. Tauber in Silicon Processing for the VLSI Era, Vol. 1, Processing Technology, Second Edition, Lattice Press, 2000,p. 801.

### SUMMARY OF THE INVENTION

The present invention provides a method for using a customized mask to select features from a standardized mask that are to be fabricated. The method is of interest in the fabrication of semi-custom integrated circuits, where the standardized mask does not have to be made for each new design.

In general, in one aspect, the invention provides a method of fabricating a semi-custom integrated circuit. In a fabrication process, the method includes using a standard mask to transfer a pattern defining a standardized set of potentially desired features to an in-process integrated circuit; using a custom mask to transfer a custom pattern to the in-process integrated circuit, the custom pattern being defined to select a portion of the potentially desired features for fabrication; and fabricating into the integrated circuit only those potentially desired features that are selected by the custom pattern. In this context, the term “in-process integrated circuit” refers to the circuit as it exists at a step in a fabrication process, for example, a step where it is covered by photoresist and is still part of a wafer.

In general, in another aspect, the invention provides an apparatus for use in fabricating a semi-custom integrated circuit. The apparatus includes a standard mask specifying a standardized set of potential desired features, and a custom mask specified to select a portion of the potential desired features for fabrication.

While the invention has general applicability, its utility can be seen in the particular example where the customized mask is for a metal interconnect layer and the standardized mask is for the via layer immediately beneath it. In this case, vias are fabricated only where the metal interconnect layer makes use of them.

For dual damascene processes that feature self-aligned vias, the invention can be practiced, using a customized metal mask to select vias from a standardized via mask, with no additional processing steps.

For processes that use two separately applied photoresist layers and two separate masks to define vias, the invention can be practiced, using a customized oversized-via mask to select vias from a standardized via mask, with no additional processing steps.

Selecting for fabrication only those vias that are actually used by the metal layer above is advantageous for two reasons. First, fabricating unused vias would add unwanted capacitance to interconnects on the previous metal layer. Second, unused vias would take up additional space on the metal layer.

These and other advantages of the invention will become apparent to those skilled in the art upon a reading of the following specification of the invention and a study of the several figures of the drawing.

### BRIEF DESCRIPTION OF THE DRAWINGS

FIG. 1 is a portion of a layout not making use of the invention.

FIG. 2 is a portion of a layout making use of the invention.

FIG. 3 is a flowchart of a portion of an integrated circuit fabrication process in accordance with the invention.

Like reference symbols in the various drawings indicate like elements.

### DETAILED DESCRIPTION

The invention provides a method for defining and using a customized mask to select features from a standardized mask that are to be fabricated. The features to be fabricated are specified by the boolean AND of the customized mask and the standardized mask. This boolean AND composite entity can be regarded as a virtual mask.

The purpose of the invention is to realize some of the potential benefits of customizing a mask layer of a semi-custom integrated circuit without having to incur the expense of actually making a customized mask for this layer.

In one example of particular interest, the standardized mask specifies a set of potentially desired vias, and the customized mask specifies the metal interconnects on the layer immediately above the via layer. Only those potentially desired vias that are covered, and therefore selected, by metal interconnects are actually fabricated.

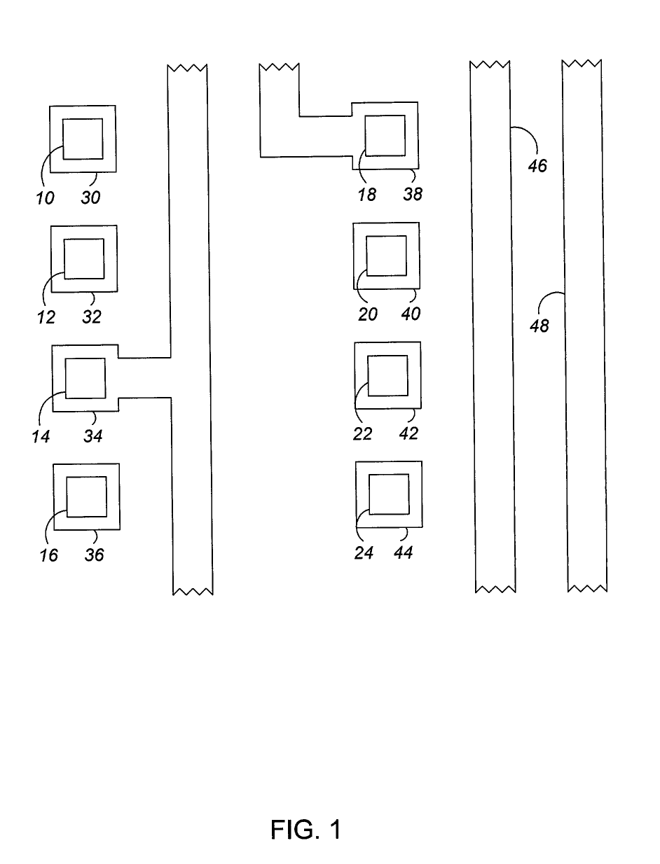

FIG. 1 illustrates a portion of a semi-custom circuit that does not practice the present invention. Vias 10, 12, 14, 16, 18, 20, 22, and 24 are part of a standardized grid of vias, all of which are fabricated, even though vias 10, 12, 16, 20, 22, and 24 are unused. According to the design rules for the fabrication process, each via must be covered by metal, so metal caps 30, 32, 36, 40, 42, and 44 cover the unused vias but serve no other function. Metal interconnect 34 connects to via 14 and metal interconnect 38 connects to via 18. Metal interconnects 46 and 48 have no connections within the figure. The standardized grid of vias is designed to accommodate two vertical metal interconnects between columns of vias and no horizontal interconnects between rows of vias.

Some fabrication processes require that each metal area have at least a certain minimum area, and in some cases that would mean that metal caps 30, 32, 36, 40, 42, and 44 would have to be even larger than illustrated.

To practice the current invention, one would remove metal caps 30, 32, 36, 40, 42, and 44 from the customized metal mask, and use a manufacturing process in which the absence of the metal caps would cause vias 10, 12, 16, 20, 22, and 24 not to be fabricated.

The virtual via mask specified by the boolean AND of the customized metal mask and the standardized via mask is more limiting that a customized via mask would be, because one cannot run a metal interconnect over a potentially desired vias without selecting it. But the virtual via mask is free, while an actual customized via mask would be expensive.

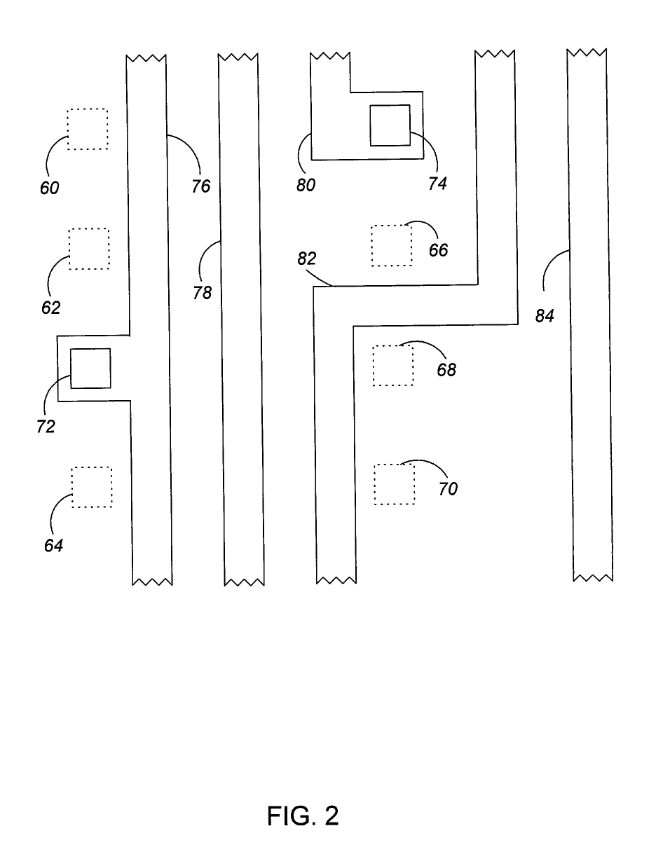

Not fabricating unused vias leaves more space for routing on the metal layer than would be available if all potentially desired vias were actually fabricated. FIG. 2 illustrates an example. It has the same via grid spacing and uses the same design rules as FIG. 1, but allows up to three vertical interconnects (not two) between unused via locations and one horizontal interconnect (not zero) between unused via locations. For example, interconnects 76, 78, and 82 can be routed between unused via locations 64 and 70, and interconnect 82 can be routed between unused via locations 66 and 68.

In principle, there should be a design rule specifying the minimum spacing between a metal interconnect and a potentially desired vias that is unused. However, most design rule sets do not have such a rule, because they do not foresee drawing vias on the standardized via mask that turn out not to be fabricated. Such a design rule would depend not only on worst case mask misalignment and critical dimension tolerances but also on the specific physical mechanism used for accomplishing the boolean AND of the metal and via masks. In some cases, it might even be acceptable for metal and via masks to overlap slightly under conditions of worst case alignment and critical dimension tolerances, thus specifying an unwanted via sliver, provided that such a via sliver had no chance of surviving subsequent processing steps.

The present invention may be practiced in a number of different ways, by adapting or adopting an existing fabrication process technology. Which embodiment is preferred depends on which fabrication process is selected.

If the baseline fabrication process fabricates vias and metal independently, and therefore does not provide a natural opportunity for these masks to construct the required boolean AND virtual mask, then one or more processing steps must be added to provide such an opportunity.

As a first example, the following steps can be used to fabricate via holes: deposit photoresist, expose using the via mask, expose using the metal mask, develop, etch vias, and strip photoresist. The via mask must be a clear field mask; that is, it must be opaque where vias are specified and transparent elsewhere. Likewise, the metal mask must be a clear field mask; that is, it must be opaque where metal is specified and transparent elsewhere. Finally, when the photoresist is developed, it must be possible to remove only the areas that have not been exposed. For this purpose, a negative photoresist can be used. Alternatively, a positive photoresist can be used, and then developed in a special way that produces a reversal of the image. This method has just more step than a conventional process: the exposure step using the metal mask. However, details of some of the other steps differ from those of a conventional process.

Alternatively, as a second example, the following steps can be used to fabricate via holes: deposit a positive photoresist, expose partially using the via mask, expose partially using the metal mask, develop, etch vias, and strip photoresist. In this case, the via mask must be a dark field mask; that is, it must be transparent where vias are specified and opaque elsewhere. Likewise, the metal mask must be a dark field mask; that is, it must be transparent where metal is specified and opaque elsewhere. Finally, the photoresist must be of sufficiently high contrast that areas exposed partially by both masks are entirely removed when the photoresist is developed, while areas exposed partially by only one mask or by neither mask are not removed. Like the previous method, this method has just one more step than a conventional process: the exposure step using the metal mask.

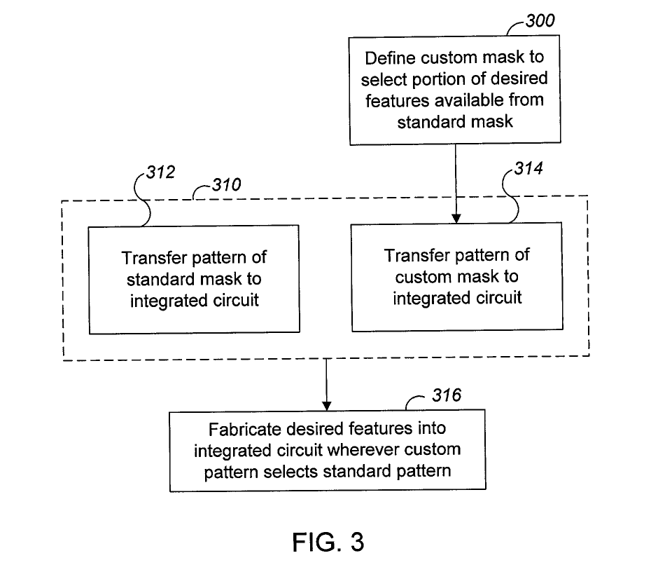

FIG. 3 summarizes key steps of the present invention. At step 312, a standard mask (in the preceding examples, the via mask) is used to transfer a pattern (potential via locations) to the integrated circuit (exposing photoresist). At step 314, a customized mask (in the preceding two examples, the metal mask) is used to transfer a pattern (interconnect locations) to the integrated circuit (further exposing the photoresist). Later, at step 316, desired features (vias) are fabricated into the integrated circuit where selected by the custom pattern. As shown in FIG. 3, in these examples, the pattern transfer steps (steps 310) can be performed in either order—that is, the masks can be interchanged. The custom mask is defined so as to select a portion of the desired features that could be fabricated for actual fabrication (step 300). Note that the desired features fabricated on an integrated circuit in accordance with the invention can be of a variety of sizes and shapes.

Alternatively, as a third example, the following steps can be used to fabricate via holes: deposit a first photoresist, expose using the via mask, develop, deposit a second photoresist, expose using the metal mask, develop, etch vias, strip photoresists. This third example has two more steps than the previous example, but the photoresists need not be good at preserving partially exposed areas.

Some fabrication processes do in fact construct the required boolean AND virtual mask from the via mask and metal mask, for the purpose of fabricating vias that are entirely under metal regardless of any mask misalignment that might occur. Such vias are called self-aligned vias. These fabrication processes can be used unmodified to practice the present invention.

The main idea of the present invention is similar to but different from the idea motivating self-aligned vias. In a fabrication process that features self-aligned vias, the metal mask selects for fabrication only that portion of a via specified on the via mask that is covered by metal. It is useful to do this because, due to the possibility of mask misalignment, the portion of a via covered by metal is not known when the via mask is made but only after the second of the two lithographic steps that define metal and via on a particular wafer. According to the present invention, the metal mask selects for fabrication only those vias which are covered by metal. It is useful to do this because, due to the business practices of semi-custom integrated circuit design, which vias will be covered by metal is not known when the standardized via mask is made but only after the customized metal mask is made for a particular design.

One fabrication process that features self-aligned vias is described by B. El-Kareh. The following steps are used to fabricate vias and metal: deposit a dielectric layer, deposit a first photoresist, expose using the via mask, develop, deposit a second photoresist, expose using the metal mask, develop, etch vias partially, etch photoresists thus transferring the metal pattern in the second photoresist to the first photoresist, etch shallow trenches for metal and finish etching vias, strip photoresist, fill vias and trenches with metal, and use chemical-mechanical polishing to remove excess metal and planarize the wafer.

Another such fabrication process is described by S. Wolf and R. N. Tauber. The following steps are used to fabricate vias and metal: deposit an inter-metal dielectric (for vias), deposit an etch stop dielectric layer, deposit a photoresist, expose using the via mask, develop, etch only the etch stop dielectric layer, strip photoresist, deposit an intra-metal dielectric (for metal), deposit photoresist, expose using the metal mask, develop, etch shallow trenches for metal and deep via holes, strip photoresist, fill vias and trenches with metal, and use chemical-mechanical polishing to remove excess metal and to planarize the wafer. During the etch step, trenches are etched where specified by photoresist, to a depth limited by the etch stop layer, while vias are etched where specified by both the patterned etch stop layer (which acts as a masking layer) and the photoresist, down to the previous metal layer. This process has the attractive feature that a semi-custom chip can be fabricated up to the point of having deposited the intra-metal dielectric and put into inventory as a standardized wafer; the subsequent processing required to customize the wafer then includes the lithographic step for metal, but not the lithographic step for vias.

Another fabrication process that features self-aligned vias is described by K. Ueno et al. in the 1995 Symposium on VLSI Technology Digest of Technical Papers. The following steps are used to fabricate vias and metal: deposit a dielectric layer, deposit an etch stop dielectric layer, deposit photoresist, expose using the metal mask, develop, etch shallow trenches into both dielectric layers, strip photoresist, deposit photoresist, expose using via mask, develop, etch via holes, strip photoresist, strip etch stop layer, fill vias and trenches with metal, and use chemical-mechanical polishing to remove excess metal and planarize the wafer. During the via etch step, vias are etched where specified by both the patterned etch stop layer (which acts as a masking layer) and the photoresist. Alternatively, instead of etching trenches into both dielectrics and then stripping photoresist, one could etch only the etch stop layer, strip photoresist, and then etch trenches into the remaining dielectric using the etch stop layer as a mask. Also, alternatively, one could omit stripping the etch stop layer.

Yet another fabrication process that features self-aligned vias is described by Michael A. Corbett and John C. Davis in Solid State Technology magazine, October 2001, pp. 40-44. The following steps are used to fabricate vias and metal: deposit a dielectric layer, deposit a first hard mask layer, deposit a second hard mask layer, deposit photoresist, expose using the metal mask, develop, etch the second hard mask layer, strip photoresist, deposit photoresist, expose using the via mask, develop, etch the first hard mask layer, partially etch vias into the dielectric layer while simultaneously stripping the photoresist, etch the first hard mask layer thus transferring the metal pattern in the second hard mask layer to the first hard mask layer, etch trenches into the dielectric layer while simultaneously completing the etching of vias, strip the second hard mask layer, strip the first hard mask layer, fill vias and trenches with metal, and use chemical-mechanical polishing to remove excess metal and planarize the wafer. In this process, at least one hard mask layer separates the dielectric layer from photoresist, so that stripping photoresist cannot damage the dielectric layer. At the step where the first hard mask layer is first etched, vias are etched into the first hard mask layer only where specified by the via pattern in photoresist AND the metal pattern in the second hard mask.

To reiterate, many fabrication processes feature self-aligned vias, and each one of them can be used without modification to practice the present invention.

Some fabrication processes use the following steps to fabricate via holes: deposit first photoresist, expose using first via mask, develop, deposit second photoresist, expose using second via mask, develop, etch vias, strip photoresists. The reason is as follows. The first photoresist is thin, so that it can be patterned precisely by the first via mask. However, thin photoresist is likely to suffer from pinhole defects. The second photoresist is thick, to combat the problem of pinhole defects, and the second via mask has oversized vias, so that it does not have to be patterned precisely. In summary, the first photoresist provides the precision and the second photoresist provides protection from pinhole defects. The present invention can be practiced using such a fabrication process as follows. The first via mask contains a standardized set of potential via locations, and the second via mask contains oversized versions of the vias actually used in a custom design. In this case, because vias are selected by an oversized via mask rather than by a metal mask, the metal mask has the flexibility to route metal over an unused potential via location. However, there is still the limitation that those vias which do occur in the customized design occur in standardized places. Using this approach, the first via mask is standardized, so it does not contribute to the cost of the customized mask set for a semi-custom chip design. Furthermore, the second via mask, since it contains only oversize features that do not have to be precise, can be less expensive than if it had to have smaller, more precise features.

The invention has been described in terms of particular embodiments. Other embodiments are within the scope of the following claims. For example, steps of the invention can be performed in a different order and still achieve desirable results.

What is claimed is:

1. A method of fabricating a semi-custom integrated circuit, the method comprising:
performing the following steps in a fabrication process:
using a standard mask to transfer a pattern defining a standardized set of potentially desired features to an in-process integrated circuit;
using a custom mask to transfer a custom pattern to the in-process integrated circuit, the custom pattern being defined to select a portion of the potentially desired features for fabrication; and
fabricating into the integrated circuit only those potentially desired features that are selected by the custom pattern.

2. The method of claim 1, wherein:
the standard mask is used after the custom mask is used in the fabrication process.

3. The method of claim 1, wherein:
the standard mask is used before the custom mask is used in the fabrication process.

4. The method of claim 3, wherein:
the integrated circuit is placed in inventory after the standard mask is used and before the custom mask is used.

5. The method of claim 1, wherein:
the desired features are vias;
the standard mask specifies a standardized set of potentially desired vias;
the custom mask specifies a customized set of interconnects; and
a via from the set of potentially desired vias is fabricated into the integrated circuit only wherever one of the standardized set of potentially desired vias and one of the customized set of interconnects overlap.

6. The method of claim 5, further comprising:
depositing a first photoresist, exposing the first photoresist using the standard mask, and developing the first photoresist, thereby removing the first photoresist from all of the standardized set of potentially desired vias;
depositing a second photoresist, exposing the second photoresist using the custom mask, and developing the second photoresist, thereby removing the second photoresist from all of the customized set of interconnects; and
fabricating vias into the integrated circuit wherever both the first photoresist and the second photoresist have been removed during development.

7. The method of claim 6, wherein the second photoresist, as patterned by the custom mask, is also used to fabricate the customized set of interconnects.

8. The method of claim 5, further comprising:
using the standard mask to fabricate into the integrated circuit a masking layer having an image of the standardized set of potentially desired vias; and
later using the masking layer and the custom mask to specify where vias are to be fabricated.

9. The method of claim 8, further comprising:
depositing a photoresist, exposing the photoresist using the custom mask, and developing the photoresist, thereby removing the photoresist from all of the customized set of interconnects; and
later using the developed photoresist to fabricate the customized set of interconnects.

10. The method of claim 5, further comprising:
using the custom mask to fabricate into the integrated circuit a masking layer having an image of the customized set of interconnects; and
later using the masking layer and the standard mask to specify where vias are to be fabricated.

11. The method of claim 10, wherein the masking layer is also used to fabricate the customized set of interconnects.

12. The method of claim 5, wherein:
the standard mask is opaque at the standardized set of potentially desired vias and transparent elsewhere; and
the custom mask is opaque at the customized set of interconnects and transparent elsewhere;
the method further comprising:
depositing a photoresist;
using both the standard mask and the custom mask to expose the photoresist; and
developing the photoresist so that unexposed areas are removed.

13. The method of claim 5, wherein:
the standard mask is transparent at the standardized set of potentially desired vias and opaque elsewhere; and
the custom mask is transparent at the customized set of interconnects and opaque elsewhere;
the method further comprising:
depositing a photoresist;
using both the standard mask and the custom mask to expose the photoresist partially, so that the photoresist is completely exposed only where both the standard and the custom masks allow the photoresist to be exposed; and
developing the photoresist so that only completely exposed areas are removed.

14. The method of claim 1, wherein:
the desired features are vias;
the standard mask specifies a standardized set of potentially desired vias;
the custom mask specifies a customized set of oversized vias; and
a via from the set of potentially desired vias is fabricated into the integrated circuit only wherever one of the standardized set of potentially desired vias and one of the specified oversized vias overlap.

15. An apparatus for use in a fabrication process for fabricating a semi-custom integrated circuit, comprising:
a standard mask specifying a standardized set of potential desired features; and
a custom mask specified to select a portion of the potential desired features for fabrication.

16. The apparatus of claim 15, wherein:
the desired features are vias;
the standard mask specifies a standardized set of potentially desired vias; and
the custom mask specifies a customized set of interconnects.

17. The apparatus of claim 15, wherein:
the desired features are vias;
the standard mask specifies a standardized set of potentially desired vias; and
the custom mask specifies a customized set of oversized vias.
